(19) United States
(12) Patent Application Publication
(10) Pub. No.: US 2007/0085152 A1
(43) Pub. Date: Apr. 19, 2007

(54) Reduced area dynamic random access memory (DRAM) cell and method for fabricating the same

(75) Inventors: Douglas Blaine Butler, Colorado Springs, CO (US); Chia-Shun Hsiao, Hsinchu (TW); Jung-Wu Chien, Hsinchu (TW); Chih-Hsun Chu, Hsinchu (TW)

Correspondence Address: HOGAN & HARTSON LLP, ONE TABOR CENTER, SUITE 1500, 1200 SEVENTEENTH ST, DENVER, CO, 80202, US

(73) Assignee: ProMOS Technologies PTE.LTD. Singapore

(21) Appl. No.: 11/250,822

(22) Filed: Oct. 14, 2005

(51) Int. Cl. H01L 29/76

(52) U.S. Cl. 257/401

(57) ABSTRACT

A reduced area dynamic random access memory (DRAM) cell and method for fabricating the same wherein the cell occupies an area smaller than one photolithography pitch by two photolithography pitches through the formation of sidewall spacers along a first pattern to define a first portion of the active region of the memory cell and a second orthogonally oriented pattern to define a second portion of the active region of the memory cell thereby creating a ladder shaped active region for a column of the memory cells.

### BACKGROUND OF THE INVENTION

The present invention relates, in general, to the field of integrated circuit memory devices and those devices incorporating embedded memory arrays. More particularly, the present invention relates to a reduced area dynamic random access memory (DRAM) cell and method for fabricating the same.

An early innovation in DRAMs was the implementation of a “folded bitline” architecture, with previous designs employing a spread-eagle or “open bitline” design. An open bitline architecture a memory cell is connected to each bitline along an activated wordline. In comparison, with a folded bitline architecture, a memory cell is connected to half of the bitlines along an activated wordline. Generally, this connection is effectuated along every other bitline, while for quarter pitch memory cells, it is along every other pair of bitlines instead. An advantage of the folded bitline architecture is that a bitline that is not connected to a memory cell can be used as a reference bitline for a bitline that is connected to a memory cell. Since the reference bitline and the bitline connected to the memory cell are located in the same array, they can be twisted to minimize signal distortion due to bitline-to-bitline coupling.

The folded bitline architecture limits the minimum DRAM memory cell area to one lithographic pitch by two lithographic pitches assuming that the bitlines are all on the same level, lithographically patterned and the wordlines are all on the same level and lithographically patterned. In common industry parlance, half of the lithography pitch is denominated as “F” (with reference to the minimum printable Feature), so an area of 8F² (or one lithographic pitch by two lithographic pitches) is the lower limit for a folded bitline DRAM memory cell patterned in a conventional manner as described above.

The most common layout for a folded bitline DRAM memory cell is one bitline by two wordline pitches, or 2F by 4F. Each folded bitline memory cell, therefore, has a wordline that connects its capacitor to the bitline and a “passing” wordline that performs no function in that particular DRAM cell. While it may be possible to provide a layout of two bitlines and one wordline per folded bitline memory cell, no such implementations are currently known.

At least one manufacturer (e.g. Micron® Technology, Inc.) has recently announced a 6F² DRAM memory cell utilizing an open bitline architecture. The cell is referred to as a capacitor-over-bitline-stack memory cell and the reduction in area has been achieved by eliminating the passing wordline from the memory cell. However, the provision of an additional “dummy” wordline is now made necessary between pairs of memory cells to provide isolation between capacitors. The resultant layout means that each cell is one bitline pitch by 1.5 wordline pitches or 2F by 3F.

In any event, this particular approach is not applicable to trench DRAM memory cells due the fact that the trench is provided under the “passing” wordline. A typical trench DRAM memory cell contains one bitline and two wordlines, with one of the latter being a “passing” wordline. The bitline contact is typically shared between two memory cells and the trench capacitors are separated by half of the minimum pitch, or “F”.

Therefore, it would be desirable to increase this spacing because one method of increasing the trench capacitor capacitance is to increase the diameter of the trench some distance below the top of the trench. However, the capability of increasing this diameter is necessarily limited by the concomitantly increased possibility of trench-to-trench shorts due to the resultant decreased trench-to-trench spacing. Ultimately, it would be desirable to define a trench DRAM memory cell that can be constructed in an area of less than 8F².

### SUMMARY OF THE INVENTION

Disclosed herein is a reduced area DRAM cell and method for fabricating the same wherein the active region pitch is less than the minimum lithography pitch and which provides essentially ladder shaped and overlapping active regions unlike previous designs wherein the active regions associated with a given bitline do not overlap with active regions associated with the same bitline.

In accordance with the disclosure of the present invention, there is provided a trench DRAM memory cell structure that can be provided in an area of less than 8F² and that also provides a trench-to-trench spacing that is larger than F. In a particular embodiment with the active area patterned at F and the nitride sidewall spacer at 0.5F, a 6F² memory cell can be readily implemented in accordance with the technique of the present invention.

Particularly disclosed herein is an integrated circuit device incorporating a memory array having a first plurality of wordlines and a second plurality of perpendicularly disposed bitlines. The memory array comprises a plurality of active regions comprising first and second oppositely extending, substantially parallel and spaced apart end portions and a perpendicularly disposed medial portion interconnecting the first and second end portions.

Also disclosed herein is an integrated circuit device incorporating a memory array having a first plurality of wordlines and a second plurality of perpendicularly disposed bitlines. The memory array comprises a plurality of interdigitated active regions coupled to each of the bitlines, with the active regions configured such that the active regions coupled to a given one of the bitlines overlap with others of the active regions coupled to the given one of the bitlines.

Further disclosed herein is an integrated circuit device comprising a memory array including a plurality of active regions coupled to a bitline, wherein the pitch of the active regions is less than a minimum photolithographic pitch.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1A is a top plan view of a portion of an integrated circuit device incorporating a group of reduced area memory cells in accordance with a representative embodiment of the present invention as disclosed herein;

FIG. 1B is a side elevational, cross-sectional view of the portion of the integrated circuit device of FIG. 1A taken substantially along section line A-A thereof following an arsenic (As) doped level 3 polysilicon (poly) chemical mechanical polishing (CMP) operation and a photolithographic operation comprising an As poly 3 layer etch back;

FIGS. 2A and 2B are follow on top plan and side elevational, cross-sectional views respectively of the portion of the integrated circuit device of the preceding figures showing a level 3 polysilicon etching operation which is sufficiently deep to be below the collar, followed by a photoresist stripping step and a level 3 polysilicon recess etch operation such that the recess is below the silicon surface;

FIG. 3A is a follow on top plan view of the portion of the integrated circuit device of the preceding figures;

FIGS. 3B and 3C are side elevational, cross-sectional views of the portion of the integrated circuit device of FIG. 3A taken substantially along section lines A-A and B-B respectively following a chemical vapor deposition (CVD) of borosilicate (boron doped) glass (BSG) in ozone, followed by a polysilicon deposition, an oxide deposition, a deep ultra-violet (DUV) lithographic step and an oxide etch;

FIGS. 4A and 4B are follow on top plan and side elevational, cross-sectional views respectively of the portion of the integrated circuit device of the preceding figures following a photoresist and anti-reflective coating (ARC) stripping step and nitride spacer deposition and etchback steps;

FIG. 5A is a further follow on top plan view of the portion of the integrated circuit device of the preceding figures;

FIGS. 5B and 5C are side elevational, cross-sectional views of the portion of the integrated circuit device of FIG. 5A taken substantially along section lines B-B and C-C respectively following a photolithographic operation to define the active area at the bitline contacts with the periphery being covered with photoresist and an oxide etching operation with no etching of the nitride or polysilicon;

FIG. 6A is yet another further follow on top plan view of the portion of the integrated circuit device of the preceding figures;

FIGS. 6B, 6C and 6D are various side elevational, cross-sectional views of the portion of the integrated circuit device of FIG. 6A taken substantially along section lines A-A, B-B and C-C thereof following a photoresist and ARC stripping step, a polysilicon hard mask etch and a nitride/oxide etch;

FIG. 7A is still another further follow on top plan view of the portion of the integrated circuit device of the preceding figures;

FIGS. 7B, 7C and 7D are various side elevational, cross-sectional views of the portion of the integrated circuit device of FIG. 7A taken substantially along section lines A-A, B-B and C-C thereof following a shallow trench isolation (STI) silicon etching step, a wet BSG etch, a nitride pullback etch, an oxidation rapid thermal processing (RTP) step, a chemical vapor deposition (CVD) high density plasma (HDP) oxide deposition and CVD HDP oxide CMP operation; and

FIGS. 8A and 8B are final top plan and side elevational, cross-sectional views respectively of the portion of the integrated circuit device of the preceding figures showing the isolation oxide and active area regions (having the gate mask illustrated in outline for sake of clarity) with the trench shown as ending the active region and the buried strap being only on the side of the trench away from the semi-circle.

### DESCRIPTION OF A REPRESENTATIVE EMBODIMENT

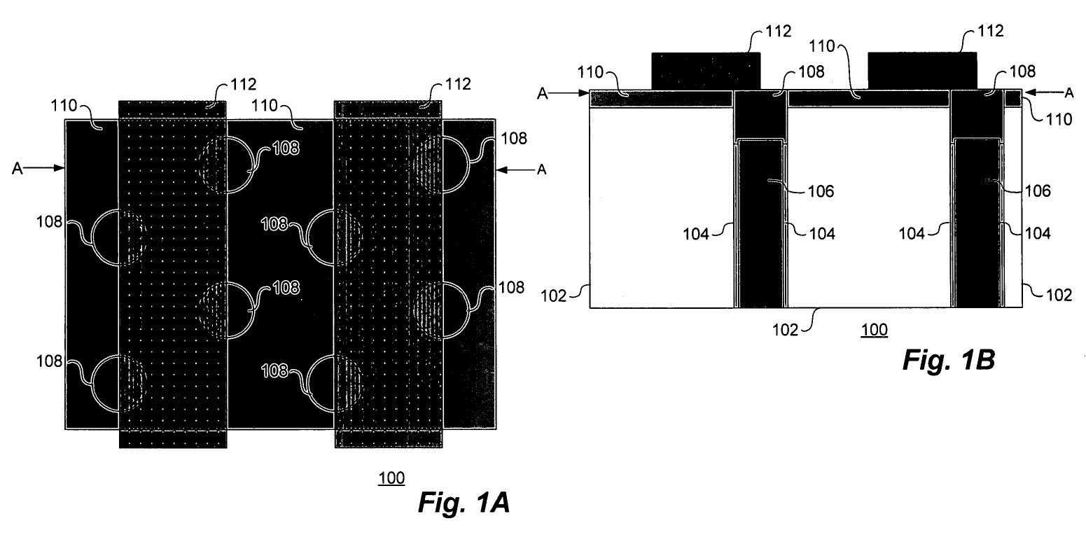

With reference now to FIG. 1A, a top plan view of a portion of an integrated circuit device 100 incorporating a group of reduced area memory cells in accordance with a representative embodiment of the present invention is shown. FIG. 1B, is a side elevational, cross-sectional view of the portion of the integrated circuit device 100 of FIG. 1A taken substantially along section line A-A thereof. The integrated circuit device 100, as fabricated to this point in the processing sequence, may be manufactured utilizing a process flow commonly employed by various DRAM manufacturers including ProMOS® Technologies, assignee of the present invention.

The integrated circuit device 100 is formed, for example, on a silicon substrate 102 into which are formed a number of oxide collars 104 substantially surrounding the periphery of trench polysilicon regions 106. The polysilicon regions 106 and surrounding oxide collars 104 are each covered by an arsenic (As) doped polysilicon (poly) 3 regions 108 which are surrounded on the surface of the silicon substrate 102 by a nitride layer 110. As a result of a chemical mechanical polishing (CMP) operation, the surface of the device 100 comprising the As poly 3 regions 108 and surrounding nitride layer 110 is planarized. Photoresist is then patterned on their upper surface to produce photoresist strips 112, each overlapping one half of adjacent As poly 3 regions 108 as shown. The photoresist strips 112 are used to protect one half of each trench, allowing portions of the As poly 3 regions 108 to be etched away (or otherwise removed) from one half of each trench.

It should be noted that a diffusion barrier is commonly used between the arsenic polysilicon 3 regions 108 and the materials to the sides and below them. Due to the relative thinness of the diffusion barrier layer with respect to other device features, its proportions are so small that it has not been illustrated herein for purposes of clarity only.

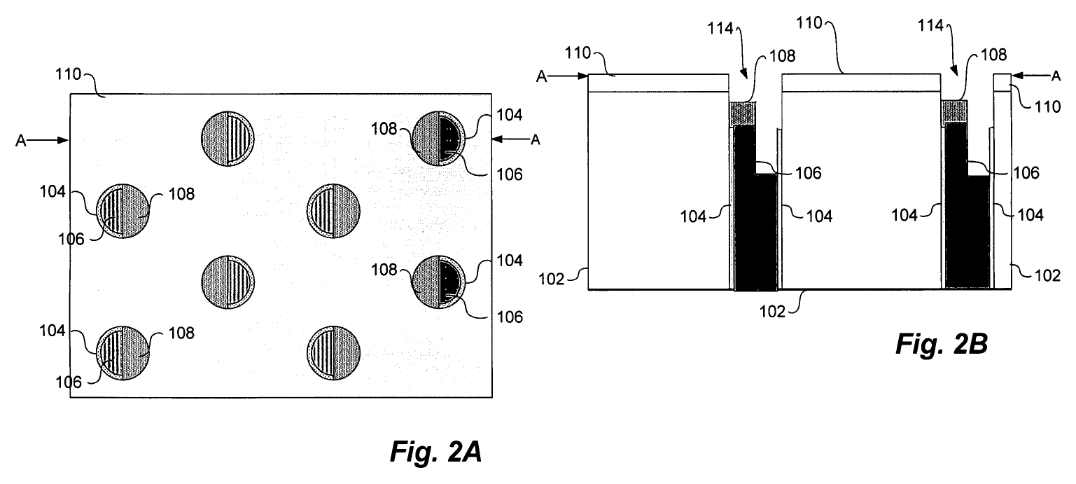

With reference additionally now to FIGS. 2A and 2B, follow on top plan and side elevational, cross-sectional views respectively of the portion of the integrated circuit device of the preceding figures are illustrated. Like structure to that previously illustrated and described is like numbered and the foregoing description thereof shall suffice herefor. As shown, an anisotropic As poly 3 region 108 etching operation is performed within recesses 114 (as defined by the photoresist strips 112) which will ultimately be sufficiently deep as to remove one half of the As poly 3 regions 108 and a portion of the underlying trench polysilicon regions 106 to below the level of the oxide collars 104. This etching operation is then followed by a photoresist 112 stripping step and a further As poly 3 region 108 recess etch operation such that the recessed surface of the As poly 3 region 108 is below the nitride layer 110 to silicon substrate 102 interface.

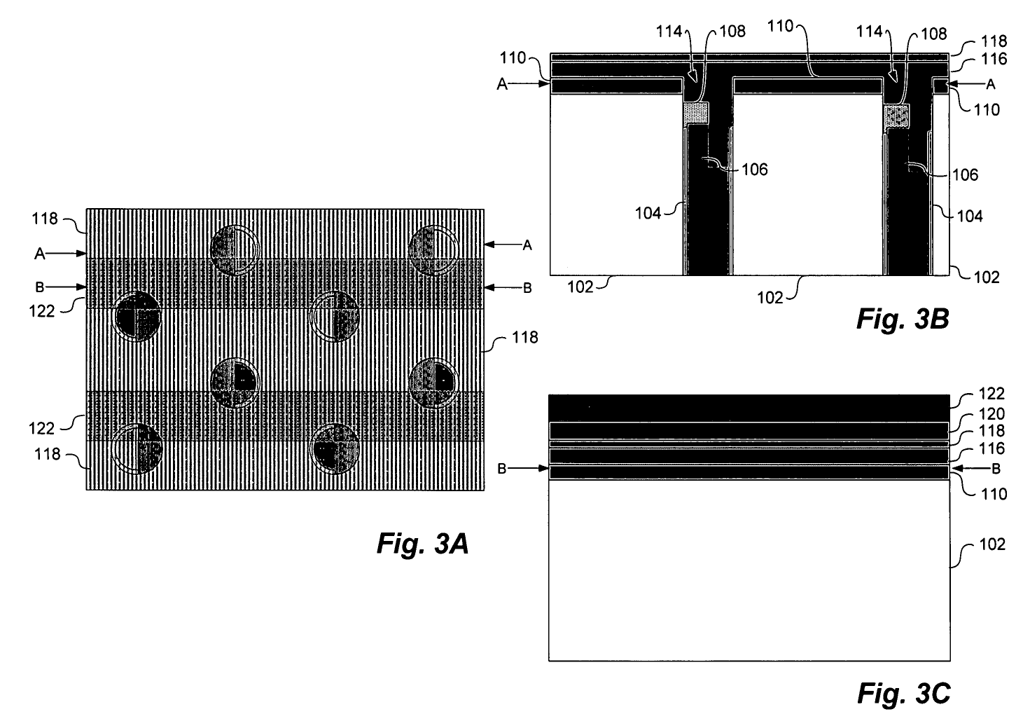

With reference additionally now to FIG. 3A, a follow on top plan view of the portion of the integrated circuit device 100 of the preceding figures is shown. FIGS. 3B and 3C depict corresponding side elevational, cross-sectional views of the portion of the integrated circuit device of FIG. 3A taken substantially along section lines A-A and B-B respectively.

As shown in FIG. 3B in particular, at this point, a chemical vapor deposition step (CVD) of borosilicate (boron doped) glass (BSG) in ozone is performed to deposit an oxide layer 116 to a thickness adequate to fill the recesses 114 created by the preceding As poly 3 etch operation. As further shown in FIG. 3C, an additional polysilicon layer 118 layer and an additional oxide layer 120 are then deposited over the oxide layer 116. A deep ultra-violet (DUV) lithographic step in conjunction with patterned photoresist 122 and a further oxide etch operation is performed resulting in the structure shown in FIGS. 3A and 3C.

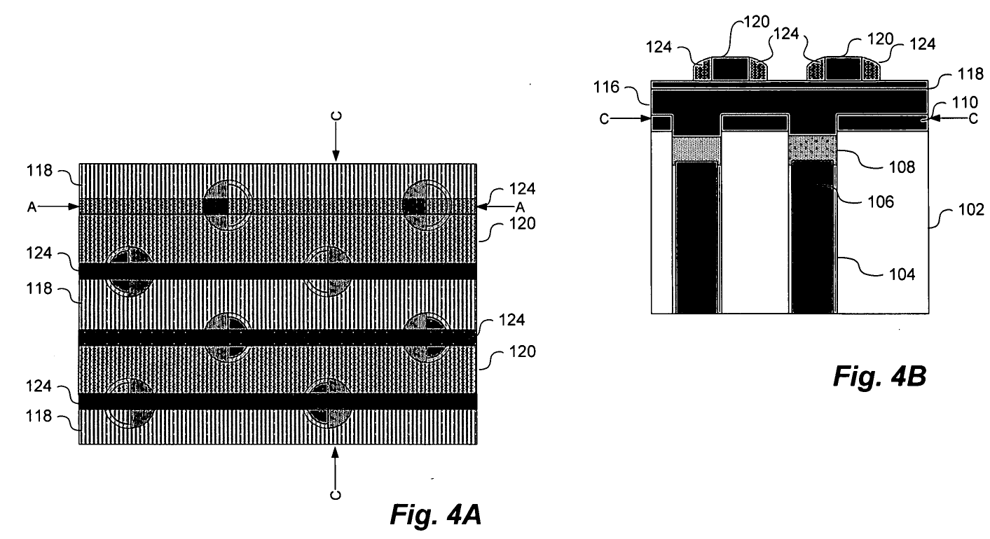

With reference additionally now to FIGS. 4A and 4B, follow on top plan and side elevational, cross-sectional views respectively of the portion of the integrated circuit device 100 of the preceding figures are shown. At this point, the photoresist 122 is removed in a photoresist and anti-reflective coating (ARC) stripping step and a nitride layer is deposited and etched anisotropically leaving nitride sidewall spacers 124 as shown. The nitride sidewall spacers 124 are used to define active area regions at a pitch smaller than the lithographic pitch. Still other layers to be described hereinafter, will also define active area regions. The trench locations cannot, by definition, be active areas so the active areas occur only where the trenches do not occur.

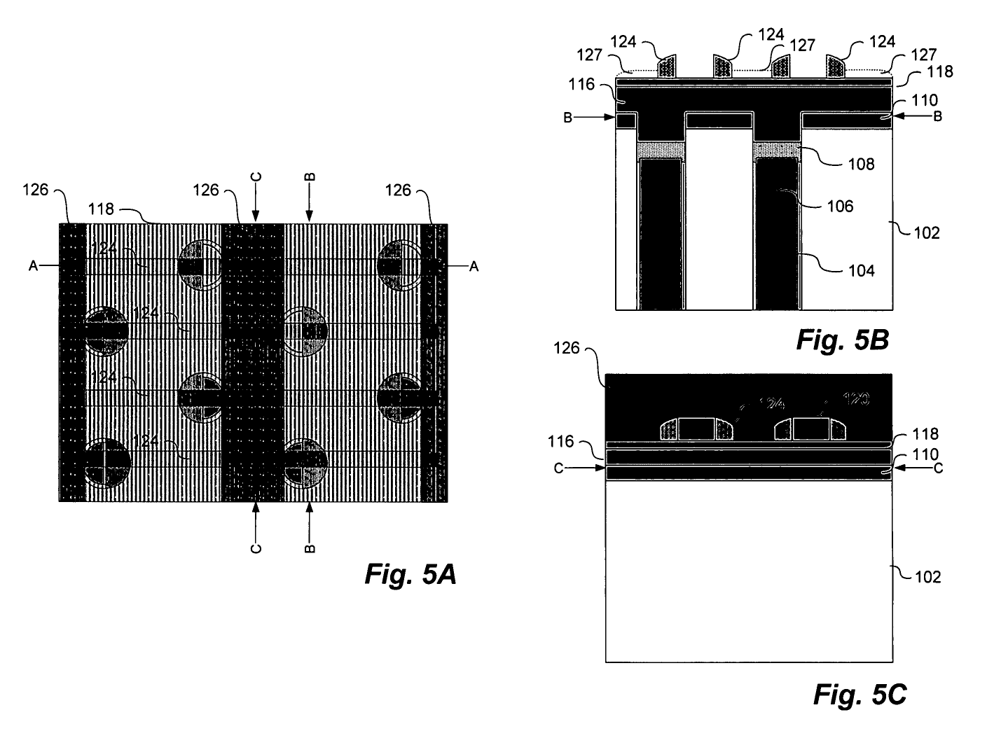

With reference additionally now to FIG. 5A, a further follow on top plan view of the portion of the integrated circuit device 100 of the preceding figures is shown. FIGS. 5B and 5C, depict side elevational, cross-sectional views of the portion of the integrated circuit device of FIG. 5A taken substantially along section lines B-B and C-C respectively.

A photolithography step is performed leaving photoresist 126 as shown in FIGS. 5A and 5C. An oxide etch is then done leaving the top oxide 120 only where it is covered by the photoresist 126 as shown in these figures. The photolithographic operation serves to define the active area at the bitline contacts with the periphery being covered with photoresist 126. The oxide 120 etching operation is carried out such that there is substantially no etching of the nitride sidewall spacers 124 or underlying polysilicon layer 118. Some residual photoresist 127 remaining between lines is acceptable.

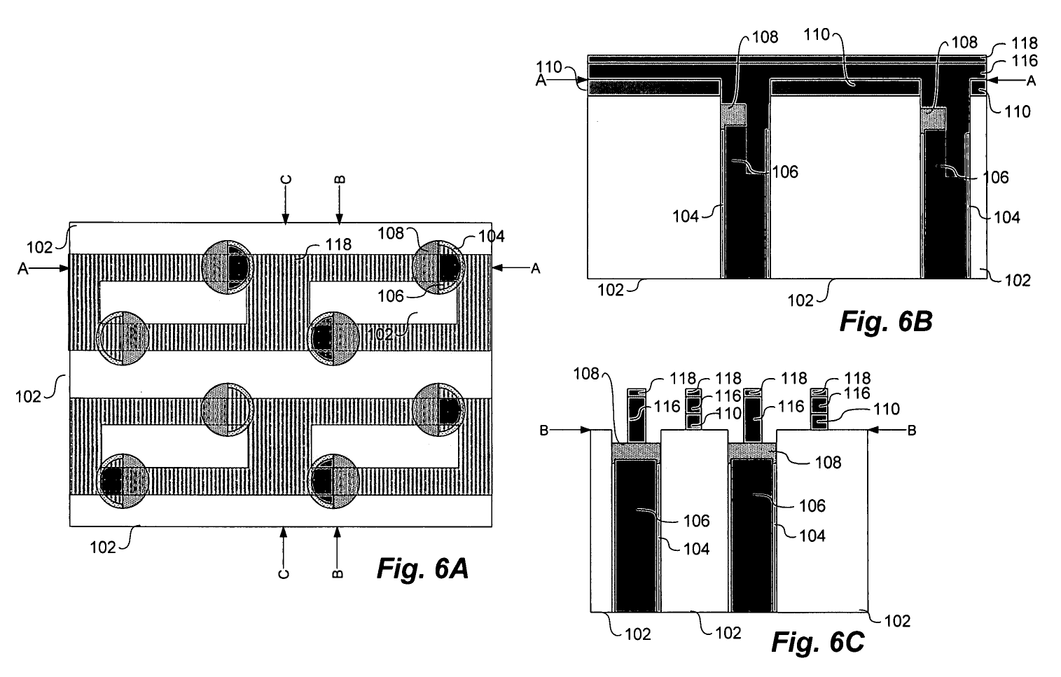

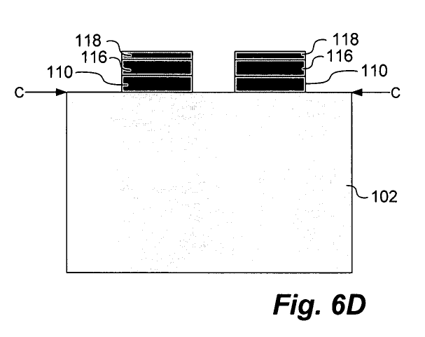

With reference additionally now to FIG. 6A, yet another further follow on top plan view of the portion of the integrated circuit device 100 of the preceding figures is shown. FIGS. 6B, 6C and 6D depict various side elevational, cross-sectional views of the portion of the integrated circuit device of FIG. 6A taken substantially along section lines A-A, B-B and C-C thereof following a photoresist 126 and ARC stripping step, a polysilicon layer 118 hard mask etch and a nitride and oxide layer 110, 116 etch.

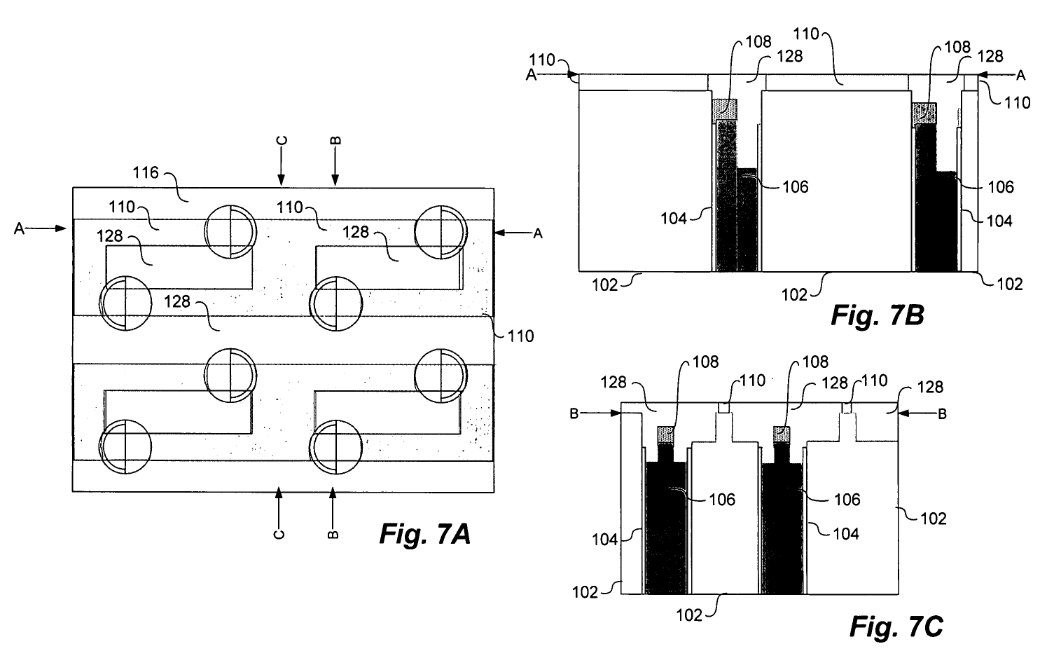

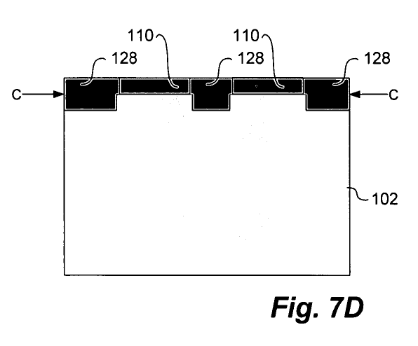

With reference additionally now to FIG. 7A, still another further follow on top plan view of the portion of the integrated circuit device 100 of the preceding figures is shown. FIGS. 7B, 7C and 7D depict various side elevational, cross-sectional views of the portion of the integrated circuit device of FIG. 7A taken substantially along section lines A-A, B-B and C-C thereof. At this point, a shallow trench isolation (STI) silicon etching step, a wet BSG etch, a nitride pullback etch and an oxidation rapid thermal processing (RTP) steps are performed. This is followed by a chemical vapor deposition (CVD) high density plasma (HDP) oxide layer 128 deposition and a planarizing CMP operation resulting in the structure shown. The array of DRAM memory cells may then be completed by any means known in the art, including the addition of wordlines and bitlines.

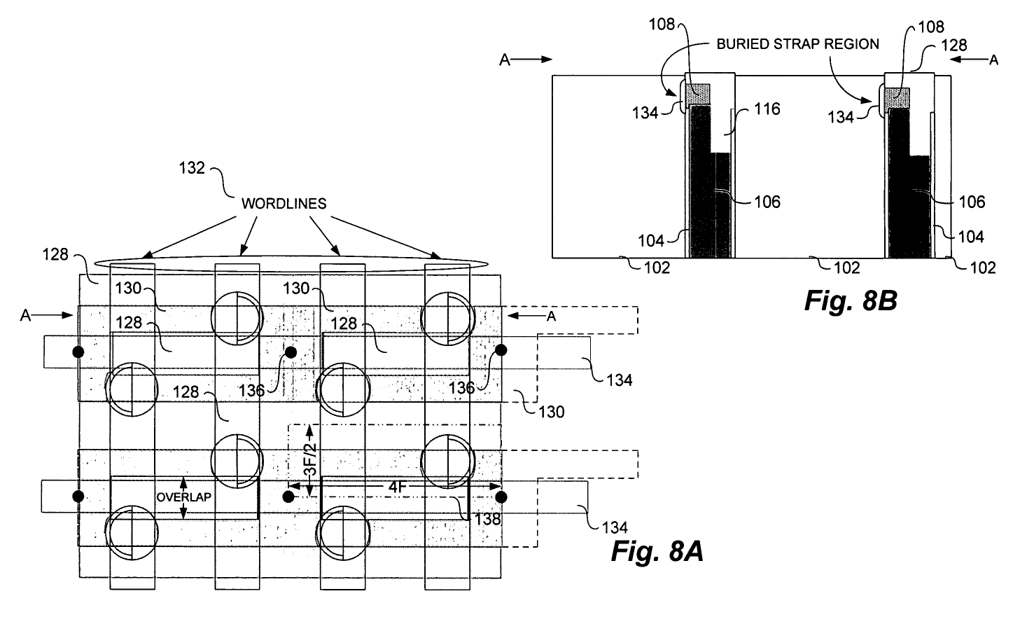

With reference additionally now to FIGS. 8A and 8B, final top plan and side elevational, cross-sectional views respectively of the portion of the integrated circuit device 100 of the preceding figures are illustrated. In these figures, the isolation oxide 128 and active area regions 130 (having the gate mask illustrated in outline for sake of clarity) are shown. The trench is also illustrated as ending the active regions 130 and the buried strap 134 being only on the side of the trench away from the semi-circle.

These figures further illustrate where the wordlines 132 will be placed. The active regions will contact the As poly 3 regions 108 only on one side of each trench. Each vertical active region will be contacted by a bitline (not shown). The bitline pitch may be twice the active area pitch if an open bitline architecture is used. This may be advantageous in order to reduce the bitline-to-bitline coupling.

With reference to FIG. 8A in particular, the interdigitated configuration of the active areas 130 is clearly shown along with the fact that active areas 130 coupled to a given one of the bitlines 134 at bitline contacts 136 will overlap each other as distinguished from conventional rectangular active area shapes which have no overlap. Each of the active areas 130 includes first and second oppositely extending and substantially parallel and spaced apart end portions and a perpendicularly disposed medial portion interconnecting the first and second end portions. Also as shown, each memory cell 138 has dimensions of substantially 3F/2 by 4F or 6F².

With reference to each of the foregoing figures, it should be noted that the depth of the trench is actually much deeper than is illustrated in the cross-sectional views and that the trench aspect ratio (depth divided by width) may be in the range of substantially 70.

While there have been described above the principles of the present invention in conjunction with specific processing steps and device structures, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

As used herein, the terms “comprises”, “comprising”, or any other variation thereof, are intended to cover a non-exclusive inclusion, such that a process, method, article, or apparatus that comprises a recitation of certain elements does not necessarily include only those elements but may include other elements not expressly recited or inherent to such process, method, article or apparatus. None of the description in the present application should be read as implying that any particular element, step, or function is an essential element which must be included in the claim scope and THE SCOPE OF THE PATENTED SUBJECT MATTER IS DEFINED ONLY BY THE CLAIMS AS ALLOWED. Moreover, none of the appended claims are intended to invoke paragraph six of 35 U.S.C. Sect. 112 unless the exact phrase “means for” is employed and is followed by a participle.

What is claimed is:

1. An integrated circuit device incorporating a memory array having a first plurality of wordlines and a second plurality of perpendicularly disposed bitlines, said memory array comprising:
a plurality of active regions comprising first and second oppositely extending, substantially parallel and spaced apart end portions and a perpendicularly disposed medial portion interconnecting said first and second end portions, said second end portion of a first one of said plurality of active regions and said first end portion of a second one of said plurality of active regions coupled to said selected one of said bitlines being overlapping.

2. The integrated circuit device of claim 1 wherein said end portions are substantially parallel to said bitlines.

3. The integrated circuit device of claim 1 wherein said medial portion is substantially parallel to said wordlines.

4. The integrated circuit device of claim 1 further comprising:
bitline contacts formed in said medial portion of said plurality of active regions.

5. The integrated circuit device of claim 4 wherein a selected one of said plurality of bitlines is coupled to adjacent ones of said plurality of active regions at said bitline contacts thereof.

6. An integrated circuit device incorporating a memory array having a first plurality of wordlines and a second plurality of perpendicularly disposed bitlines, said memory array comprising:
a plurality of active regions comprising first and second oppositely extending, substantially parallel and spaced apart end portions and a perpendicularly disposed medial portion interconnecting said first and second end portions wherein a pitch of said active regions is less than a minimum photolithographic pitch.

7. The integrated circuit device of claim 6 wherein said pitch of said active regions is spacer defined.

8. The integrated circuit device of claim 6 wherein a width of said first and second end portions is substantially F/2.

9. The integrated circuit device of claim 6 wherein said length of said interconnecting medial portion is substantially F/2.

10. The integrated circuit device of claim 6 wherein a width of said interconnecting medial portion is substantially F.

11. The integrated circuit device of claim 10 wherein said width of said interconnecting medial portion is photolithographically defined.

12. The integrated circuit device of claim 6 wherein each memory cell in said memory array is substantially 3/2F×4F in size.

13. The integrated circuit device of claim 6 wherein said memory array comprises DRAM.

14. An integrated circuit device incorporating a memory array having a first plurality of wordlines and a second plurality of perpendicularly disposed bitlines, said memory array comprising:
a plurality of interdigitated active regions coupled to each of said bitlines, said active regions configured such that said active regions coupled to a given one of said bitlines overlap with others of said active regions coupled to said given one of said bitlines.

15. The integrated circuit device of claim 14 wherein a pitch of said active regions is less than a minimum photolithographic pitch.

16. The integrated circuit device of claim 15 wherein said pitch of said active regions is spacer defined.

17. The integrated circuit device of claim 14 wherein a width of end portions of said active regions is substantially F/2.

18. The integrated circuit device of claim 14 wherein a width of a medial portion of said active regions is substantially F.

19. The integrated circuit device of claim 18 wherein said width of said medial portion is photolithographically defined.

20. The integrated circuit device of claim 14 wherein each memory cell in said memory array is substantially 3/2F×4F in size.

21. The integrated circuit device of claim 14 wherein said memory array comprises DRAM.

22. An integrated circuit device comprising:
a memory array including a plurality of active regions coupled to a bitline, wherein a pitch of said active regions is less than a minimum photolithographic pitch.

23. The integrated circuit device of claim 22 wherein said pitch of said active regions is spacer defined.

24. The integrated circuit device of claim 22 wherein a width of end portions of said active regions is substantially F/2.

25. The integrated circuit device of claim 22 wherein a width of a medial portion of said active regions is substantially F.

26. The integrated circuit device of claim 25 wherein said width of said medial portion is photolithographically defined.

27. The integrated circuit device of claim 22 wherein each memory cell in said memory array is substantially 3/2F×4F in size.

28. The integrated circuit device of claim 22 wherein said memory array comprises DRAM.

29. A method for forming an integrated circuit device pattern on a semiconductor structure comprising:
forming a plurality of spacers along a feature disposed in a first direction on said semiconductor structure; and
patterning said feature so as to provide sub-features disposed between said spacers.

30. The method of claim 29 wherein said forming said plurality of spacers is carried out by forming sidewall spacers on said feature.

31. The method of claim 29 wherein said step of forming said plurality of spacers comprises:
forming a spacer layer; and
selectively removing portions of said spacer layer.

32. The method of claim 31 wherein said spacer layer comprises a nitride layer.

33. The method of claim 31 wherein said operation of selectively removing portions of said spacer layer comprises an etching operation.

34. The method of claim 33 wherein said etching operation comprises an anisotropic etching operation.

35. The method of claim 29 wherein said operation of patterning said feature is carried out by photolithographically patterning photoresist.

36. The method of claim 29 wherein said operation of patterning said feature is carried out in a second direction substantially orthogonal to said first direction.

37. The method of claim 29 wherein said feature comprises an oxide.

38. The method of claim 29 wherein said semiconductor structure comprises a polysilicon layer on which said spacers and feature are formed.

39. The method of claim 29 wherein said semiconductor structure comprises an integrated circuit device incorporating a plurality of trench memory cells.

40. The method of claim 29 further comprising:
transferring a pattern of said sub-features and said spacers into a layer underlying said sub-features and said spacers.

41. The method of claim 40 wherein said operation of transferring said pattern is carried out by etching.

42. The method of claim 40 wherein said layer underlying said sub-features and said spacers comprises polysilicon.
